(19) United States
(12) Patent Application Publication
(10) Pub. No.: US 2025/0163566 A1
(43) Pub. Date: May 22, 2025

(54) SYSTEMS AND METHODS FOR MANUFACTURING STRUCTURES USING ELECTRON-BEAM PHYSICAL VAPOR DEPOSITION

(71) Applicant: Blue Origin, LLC, Kent, WA (US)

(72) Inventors: Weidong Song, Woodinville, WA (US); Brent Sherwood, Seattle, WA (US)

(21) Appl. No.: 18/518,300

(22) Filed: Nov. 22, 2023

(51) Int. Cl. C23C 14/30; C23C 14/56

(52) U.S. Cl. CPC C23C 14/30; C23C 14/56

(57) ABSTRACT

A kit for manufacturing a structure in space is provided. In one aspect, the kit includes an inflatable bladder having an internal wall configured to define an internal space of the structure when the bladder is inflated. The kit also includes a structural liner coupled to the internal wall of the inflatable bladder. The kit also includes one or more e-beam physical vapor deposition systems configured to be positioned within the internal space of the structure when the bladder is inflated. The one or more e-beam physical vapor deposition systems configured to form a metallic structural shell on the structural liner.

### BACKGROUND

### Field

The technology relates generally to the manufacturing of a structure through the use of vapor deposition, such as vapor deposition on a deployable structural liner.

### Description of the Related Art

Methods of manufacturing large structures for use in space typically involve building numerous small sized modular parts that are assembled on earth and launched into orbit. Numerous small sized modular parts are needed because of weight constraints. This can limit the size of the structures that are manufactured in space and increase the manufacturing and/or shipping costs of assembling large structures in space.

### SUMMARY

The embodiments disclosed herein each have several aspects no single one of which is solely responsible for the present disclosure's desirable attributes. Without limiting the scope of the present disclosure, its more prominent features will now be briefly discussed. After considering this discussion, and particularly after reading the section entitled “Detailed Description” one will understand how the features of the embodiments described herein provide advantages over existing methods of manufacturing large space habitats.

In one aspect, a kit for manufacturing a structure in space is provided. The kit includes an inflatable bladder, a structural liner, and one or more e-beam physical vapor deposition systems. The inflatable bladder has an internal wall configured to define an internal space of the structure when the bladder is inflated. The structural liner is coupled to the internal wall of the inflatable bladder. The one or more e-beam physical vapor deposition systems are configured to be positioned within the internal space of the structure when the bladder is inflated. The one or more e-beam physical vapor deposition systems are configured to form a metallic structural shell on the structural liner.

In some embodiments, the structural liner includes a braided carbon fiber liner. In some embodiments, the structural liner includes a ceramic material. In some embodiments, the metallic structural shell is formed from a high stiffness and high strength alloy. In some embodiments, the alloy is titanium or aluminum. In some embodiments, the kit includes a frame configured to support the one or more e-beam physical vapor deposition systems. In some embodiments, the frame is configured to move within the internal space while creating the metallic structural shell. In some embodiments, the frame is configured to move the one or more e-beam physical vapor deposition systems. In some embodiments, the one or more e-beam physical vapor deposition systems are configured to sequentially deposit a plurality of metallic layers on the structural liner to form the metallic structural shell. In some embodiments, the one or more e-beam physical vapor deposition systems are configured to be positioned within the inflatable bladder before it is inflated. In some embodiments, an internal surface of the structural liner is configured to define a volume when the bladder is inflated, and the one or more e-beam physical vapor deposition systems are configured to seal the volume defined by the internal surface of the structural liner. In some embodiments, the kit includes a gas source configured to inflate the bladder. In some embodiments, the inflatable bladder is configured to transform from a folded configuration to an unfolded configuration when gas from the gas source inflates the bladder. In some embodiments, the one or more e-beam physical vapor deposition systems are configured to form a metallic structural shell on the structural liner that is about 2 mm to about 3 mm thick.

In another aspect, a method of manufacturing a structure is provided. The method includes attaching a structural liner to an internal wall of an inflatable bladder. The method also includes deploying the inflatable bladder and structural liner by pressurizing the inflatable bladder. The method also includes positioning one or more e-beam physical vapor deposition systems within an internal space of the structure. The method also includes forming a metallic structural shell on the structural liner using the one or more e-beam physical vapor deposition systems.

In some embodiments, the one or more e-beam physical vapor deposition systems are positioned within the inflatable bladder before the inflatable bladder is deployed. In some embodiments, forming the metallic structural shell includes sequentially depositing a plurality of metallic layers on the structural liner. In some embodiments, forming the metallic structural shell includes depositing a plurality of metallic layers to a thickness of about 2 mm to about 3 mm. In some embodiments, the structural liner is a braided carbon fiber liner. In some embodiments, the structural liner is a ceramic material. In some embodiments, the metallic structural shell is formed from a high stiffness and high strength alloy. In some embodiments, the alloy is titanium or aluminum. In some embodiments, the method includes moving the one or more e-beam physical vapor deposition systems while forming the metallic structural shell. In some embodiments, a vacuum environment exists within a volume defined by the structural liner after deploying the inflatable bladder and the structural liner. In some embodiments, deploying the inflatable bladder and the structural liner occurs in space. In some embodiments, forming the metallic structural shell seals a volume defined by the structural liner. In some embodiments, deploying the inflatable bladder transforms the structural liner from a folded configuration to an unfolded configuration.

In another aspect, a structure is provided. The structure includes an inflatable bladder, a structural liner, and a metallic structural shell. The inflatable bladder has an internal wall configured to define an internal space when inflated. The structural liner is coupled to the internal wall of the inflatable bladder. The metallic structural shell is deposited on the structural liner by one or more e-beam physical vapor deposition systems.

In some embodiments, the metallic structural shell is from about 2 mm to about 3 mm thick. In some embodiments, the structural liner is a braided carbon fiber liner. In some embodiments, the metallic structural shell is formed from a high stiffness and high strength alloy.

### BRIEF DESCRIPTION OF THE DRAWINGS

The foregoing and other features of the present disclosure will become more fully apparent from the following description and appended claims, taken in conjunction with the accompanying drawings. Understanding that these drawings depict only several embodiments in accordance with the disclosure and are not to be considered limiting of its scope, the disclosure will be described with additional specificity and detail through use of the accompanying drawings. In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. In some drawings, various structures according to embodiments of the present disclosure are schematically shown. However, the drawings are not necessarily drawn to scale, and some features may be enlarged while some features may be omitted for the sake of clarity. It will be readily understood that the aspects of the present disclosure, as generally described herein, and illustrated in the figures, can be arranged, substituted, combined, and designed in a wide variety of different configurations, all of which are explicitly contemplated and make part of this disclosure. As noted above, the drawings as depicted are not necessarily drawn to scale. The relative dimensions and proportions as shown are not intended to limit the present disclosure.

FIG. 1 is a schematic illustration of a structure formed according to the present disclosure.

FIG. 2 is a cross-sectional view of the structure of FIG. 1 taken along line 2-2, the structure being formed with an inflatable bladder and structural liner according to the present disclosure.

FIG. 3 illustrates a braided carbon fiber liber that can be used as a structural linear according to the present disclosure.

FIG. 4 illustrates an example e-beam physical vapor deposition system according to the present disclosure.

FIG. 5 is a flow chart representing an example method of manufacturing a structure according to an embodiment of the present disclosure.

FIG. 6A illustrates the e-beam physical vapor deposition system of FIG. 4 disposed within the structure of FIG. 1, the e-beam physical vapor deposition system having formed a partial metallic structural shell on the structural liner, according to the present disclosure.

FIG. 6B illustrates the e-beam physical vapor deposition system of FIG. 4 disposed within the structure of FIG. 1, the e-beam physical vapor deposition system having formed a substantially uniform metallic structural shell on the structural liner, according to the present disclosure.

FIG. 7 is a cross-sectional view of the structure of FIG. 1 taken along line 7-7.

### DETAILED DESCRIPTION

Embodiments of the present disclosure generally relate to the manufacturing of large habitats or structures through vapor deposition on deployable structural liners. In some instances, the large structures may have diameters exceeding 10 meters. While in some instances embodiments of the present disclosure are described with reference to devices, systems, and structures being manufactured in space, the present disclosure is not intended to be limited to in-space manufacturing. Accordingly, devices, systems, and structures according to the present disclosure may also be manufactured on Earth. Non-limiting example structures include space habitats connected to space stations or space vehicles. The structures may be manufactured by deploying an inflatable bladder and depositing a metallic structural layer on a structural liner attached to an internal surface of the inflatable bladder. The metallic structural layer may be deposited using electron-beam (e-beam) physical vapor deposition (PVD).

The devices, systems, and structures and methods of manufacture described herein may provide a number of advantages. For example, packaging non-deployed inflatable bladders having integral structural liners on Earth and delivering the bladders to a location in space in accordance with embodiments of the present disclosure can reduce the overall weight of a structure (or components of a structure) being delivered to space. As such, the structure does not need to be formed by multiple modular parts. This can reduce the overall cost of manufacture. The reduction of costs is highly beneficial as current methods of in-space manufacturing of large structures are very expensive and complicated. Additionally, this can allow for the overall size of the structures to be larger. The use of e-beam PVD can also be advantageous as it can create a more structurally durable and safer structure than prior technologies. A metallic structural shell formed using the e-beam PVD systems and methods according to the present disclosure may also create a rigid interior surface that provides the benefits of an easier system integration. For instance, the rigid interior surface may allow the metallic structural shell to be integrated with other systems, such as docking ports, interior features, and windows, more effectively, for example with fewer processing steps and/or materials.

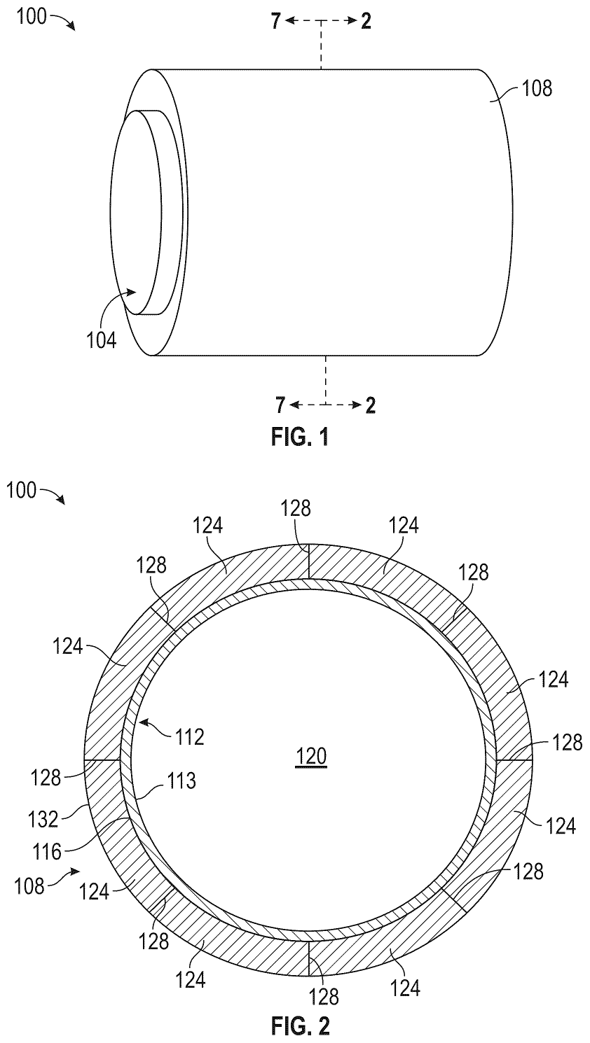

Various examples embodiments of devices, kits, systems, structures, and methods according to the present disclosure will now be described with reference to the figures. FIG. 1 is a schematic illustration of an example structure 100 manufactured according to the present disclosure. Non-limiting examples of the structure 100 include large space habitats or vessels that can be manufactured in space. Parts and tools to manufacture the structure 100 can be packaged and delivered to space in a kit according to the present disclosure. The structure 100 may be connected to a space station or space vehicle prior to, during, and/or after manufacture of the structure 100. For example, the structure 100 can be attached to a space craft or space station via a connecting port 104. The connecting port 104 may be removably connectable to the space craft or space station. The connecting port 104 can be pre-connected to an inflatable bladder 108. The connecting port 104 may include a rigid material. For example, the connecting port 104 may include a metal hardware. While the connecting port 104 is depicted as having a circular cross-section in this non-limiting example, connecting ports 104 having other cross-sectional shapes can be suitably implemented in accordance with embodiments of the present disclosure. The connecting port 104 may provide an opening in the inflatable bladder 108. In some examples, the connecting port can provide access to an internal space of the structure 100.

FIG. 2 is a cross-sectional view of the structure 100 taken along the line 2-2 as labeled in FIG. 1. The structure 100 may include the inflatable bladder 108 and a structural liner 112. The inflatable bladder 108 may have an internal wall 116 and an external wall 132. The internal wall 116 may define an internal space 120 when the inflatable bladder 108 is inflated. The inflatable bladder 108 may be connected to a gas source capable of inflating the bladder. When the inflatable bladder 108 is inflated or deployed, it may transform from a folded or packed configuration to an unfolded or unpacked configuration.

A vacuum condition may exist in the internal space 120. The vacuum condition may exist naturally or automatically without any outside intervention needed to create the vacuum environment. The natural vacuum environment may be advantageous as it can create a reliable, consistent, and/or constant vacuum environment. The natural vacuum environment may also be advantageous as it can provide the optimal environment during the use of electron-beam physical vapor deposition systems according to the present disclosure.

The structural liner 112 may be coupled or attached to the internal wall 116 of the inflatable bladder 108. An internal surface 113 of the structural liner 112 may define a volume when the inflatable bladder 108 is inflated. The inflatable bladder 108 may include one or more regions 124. For example, the inflatable bladder 108 may include one, two, three, four, fix, six, seven, eight, or more regions 124. The one or more regions 124 may be separated from adjacent regions 124 by one or more walls 128. The one or more walls 128 may extend between the internal wall 116 and the external wall 132. The walls 128 may isolate a region 124 from adjacent regions 124. The one or more regions 124 may be pressurized when the inflatable bladder 108 is inflated. The isolated nature of the one or more regions 124 may reduce a risk that the inflatable bladder 108 fails or becomes non-functional in the event that one or more of the regions 124 are damaged. The inflatable bladder 108 may serve as a multilayer insulation and micrometeoroids and orbital debris (MMOD) protection system. The inflatable bladder 108 can be an elastomeric material. Non-limiting examples include urethane, polyester copolymers, natural rubber, silicone rubber, and fluoropolymers. Once inflated, the pressure exerted on the structural liner 112 by the inflatable bladder 108 can depend on the material properties of the inflatable bladder 108 and/or the material properties of the structural liner 112, including but not limited to the materials selected to form the structural liner 112 and the inflatable bladder 108, the size of the structural liner 112 and the inflatable bladder 108, and the thickness of the materials used to form the structural liner 112 and the inflatable bladder 108. Once inflated, the pressure exerted on the structural liner 112 by the inflatable bladder can be 5, 10, 15, 20, 25, 30, 35, 40 psi, or less, or more, or any value or range defined by any of the preceding values.

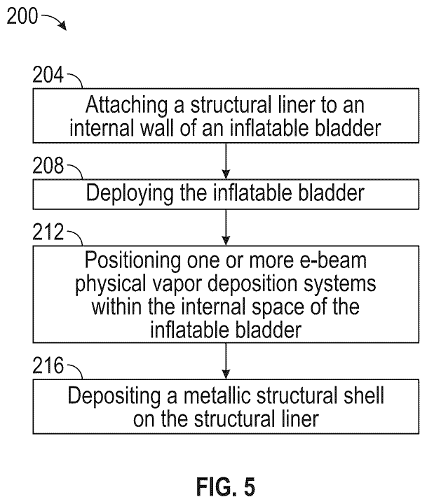

The structural liner 112 may be positioned within the inflatable bladder 108. The structural liner 112 and the inflatable 108 may be capable of moving freely relative to one another. The structural liner 112 may be coupled to the internal wall 116 of the inflatable bladder 108. For example, the structural liner 112 may be adhered to and/or sewn into the internal wall 116 of the inflatable bladder 108. The structural liner 112 may be coupled to the internal wall 116 of the inflatable bladder 108 at specific predetermined locations. For example, the structural liner 112 may be coupled to the internal wall 116 of the inflatable bladder 108 at or near valves that are used for inflating and deflating the inflatable bladder 108. The inflatable bladder 108, the structural liner 112, and/or the connecting port 104 may be assembled prior to the deployment or inflation of the inflatable bladder. This may be advantageous when the structure 100 is manufactured in space, as the inflatable bladder 108 and the structural liner 112 in a non-deployed state can be lighter for delivery into space in a kit or as unassembled components to be assembled in space. As will be described in detail below with reference to FIGS. 5-7, the inflatable bladder 108 may be used to deploy the structural liner 112 according to embodiments of the present disclosure.

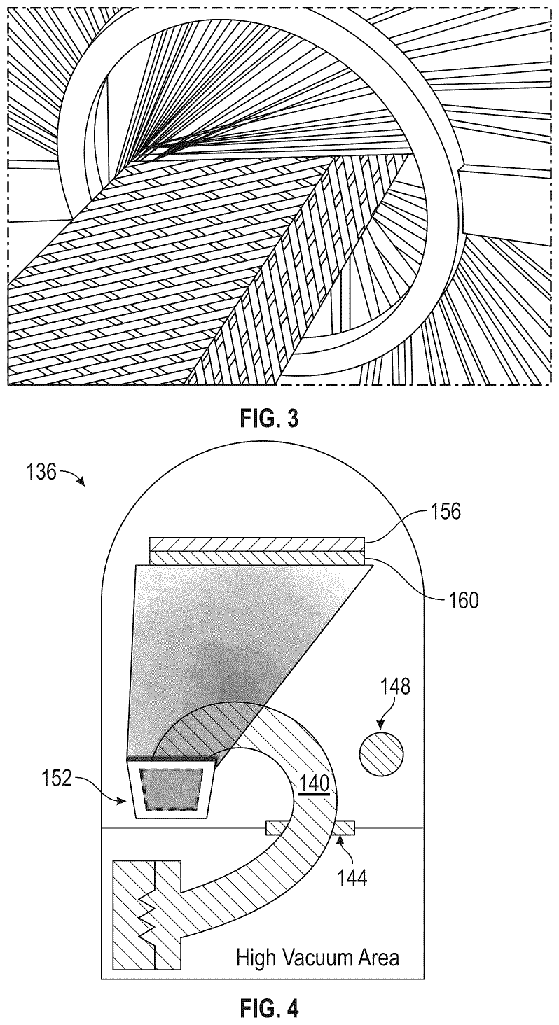

In some embodiments, the structural liner 112 may include a braided carbon fiber liner. Braiding may be used for making large structures using continuous fiber. In some embodiments of the present disclosure, high performance carbon fiber may serve as a key structural element of the structure 100. FIG. 3 illustrates an example braided carbon fiber liner during manufacture. The braided carbon fiber may be positioned as the structural liner 112 within the inflatable bladder 108.

The use of a braided carbon fiber liner as the structural liner 112 can provide many advantages. For example, the braided carbon fiber liner may be lighter and stronger than liners formed of alternative materials. The lighter and stronger aspects of the braided carbon fiber liner can allow for an advantageous strength to weight ratio in embodiments of the present disclosure. The braided carbon fiber liner being lighter can be advantageous when delivering the materials to space in a kit or as unassembled components to be assembled in space, as it may greatly reduce the overall weight of the kit for shipment to space. Additionally, the relatively light weight of the braided carbon fiber liner may allow for more carbon fiber liner to be used, which may allow for the manufacture of larger structures. Advantageously, the use of braided carbon fiber liner can also provide safety benefits. For example, braided carbon fiber liner can be structurally safer than other liners, as the redundant nature of the braided carbon fiber may tolerate or allow for local failures, while still maintaining the integrity of the assembled structure within acceptable limits. The use of braided carbon fiber liner is also advantageous as the material is not as subject to degradation as alternative materials and therefore may have a longer life. Additionally, the use of braided carbon fiber may reduce or remove the risk of creeping by preventing or limiting the structural liner 112 from undergoing deformation.

It will be understood that embodiments of the present disclosure are not limited to a structural liner 112 including braided carbon fiber, and other materials can be suitably implemented. Other non-limiting examples of materials that can be suitably implemented in the structural liner 112 include a ceramic material or a fiberglass material. The use of a fiberglass material as the structural liner 112 may be advantageous as it may be transparent which may allow for improved transmission of radio frequency waves. Additionally, a liner including fiberglass material may have a better impact resistance that a liner including braided carbon fiber. In some embodiments, the structural liner 112 may include a mix of materials or a combination of more than one material. For example, a mix or combination of braided carbon fiber liner and fiberglass may be suitably implemented in embodiments of the present disclosure. A mix or combination of materials may be advantageous as the structural liner 112 may offer the benefits of both materials.

FIG. 4 illustrates an example electron-beam (e-beam) physical vapor deposition (PVD) (referenced herein as “e-beam PVD”) system 136 according to the present disclosure. E-beam PVD may use one or more electron beams that are generated in a high vacuum area to deposit a layer or layers of material, such as a high performing alloy, on a surface. The natural vacuum environment of space can make the use of e-beam PVD for manufacturing of large structures in space more cost effective and simpler to implement than use of e-beam PVD in non-space environments, where reliably implementing and controlling a high vacuum area is costly and technically challenging.

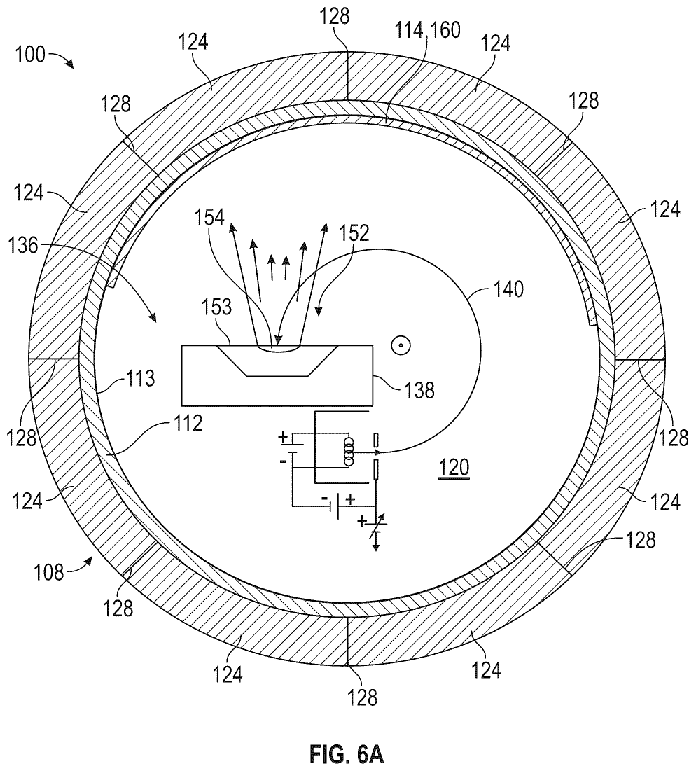

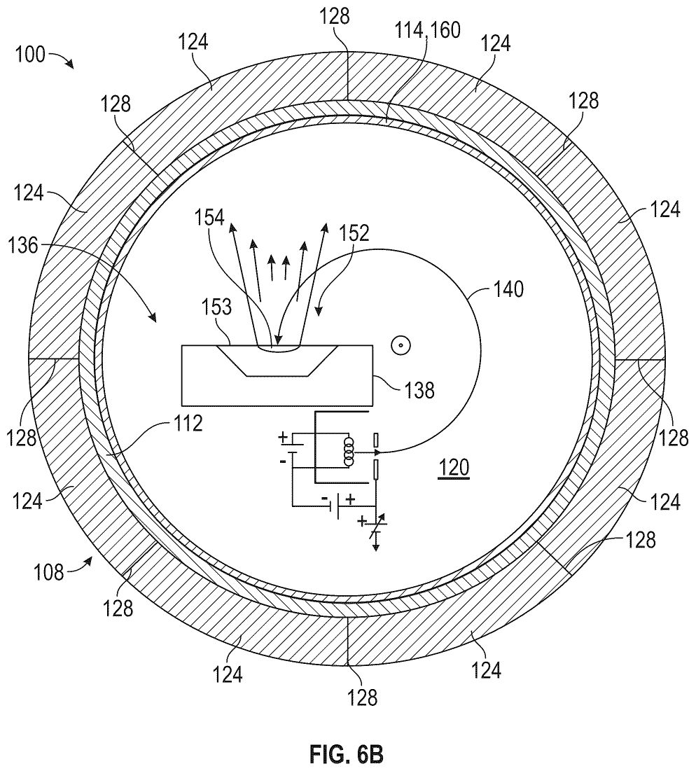

In embodiments of the present disclosure, the electron beams 140 may travel through a focusing magnet 144. In some embodiments, the electron beams 140 may be redirected by a deflecting magnet 148 to a material source 152. In some embodiments, the material source 152 may be held in a water-cooled holder 138, for example as illustrated in FIGS. 6A-6B. The material source 152 may be in the form of an ingot 153 of material, for example as illustrated in FIGS. 6A-6B. The material of the material source 152 may be a high stiffness and/or high strength metal alloy, for example titanium, magnesium, or aluminum alloys. The material of the material source 152 may be a combination of these materials. The material of the material source 152 may be a combination of high strength metal alloys at high mixing ratios. For example, the material of the material source 152 may be a high entropy alloy. The electron beams 140 may create a heated region 154 of the material source 152, for example as illustrated in FIGS. 6A-6B. The heating of the material can turn a portion of the material source 152 into vapor. The vapor can then be directed away from the e-beam PVD system 136 and applied to a substrate 156 (for example, the structural liner 112 according to the present disclosure). The process can create a structural shell 160 (for example, the metallic structural shell 114 according to the present disclosure) through stiffening. The process can be used to pneumatically seal a structure (for example, a structure 100) that is being formed according to the present disclosure. In some embodiments, the e-beam PVD system 136 can seal the volume defined by the internal surface 113 of the structural liner 112. Advantageously, the e-beam PVD system 136 according to the present disclosure can be packaged as part of a kit with other components, for example the inflatable bladder 108 and structural liner 112. The kit can be delivered to space, where the components are assembled for manufacture of a structure 100. Alternatively, the e-beam PVD system 136 according to the present disclosure can be packaged separate from the inflatable bladder 108 and/or the structural liner 112 during delivery to space.

FIG. 5 is a flow chart representing an example method 200 of manufacturing the structure 100 according to an embodiment of the present disclosure. The methods of manufacturing structures described herein are not limited to manufacturing in space. Accordingly, in some embodiments, the structures may be manufactured on Earth. The methods and structures according to the present disclosure are advantageous, as the structures may be manufactured at or near the location of use, whether that be in space, on Earth, or another planet. The method 200 begins at block 204, where the structural liner 112 may be assembled with, for example coupled or attached to, the internal wall 116 of the inflatable bladder 108, according to present disclosure. The assembled inflatable bladder 108 and structural liner 112 may remain undeployed for transportation. For example, the structural liner 112 may be attached to the internal wall of the inflatable bladder 108 prior to delivering the inflatable bladder 108 to space or other location of use. The undeployed structural liner 112 and inflatable bladder 108 may be packaged in a kit for shipment to space. In one non-limiting embodiment, the kit may be transported to space in a payload fairing of a rocket.

Moving to block 208, the inflatable bladder 108 may be deployed. The inflatable bladder 108 may be deployed at or near the location of final use. For example, in embodiments where the inflatable bladder 108 is deployed in space, the inflatable bladder 108 may include a connecting port 104 that is connected to a corresponding connecting port of a space station or space vehicle. Once the connecting port 104 of the inflatable bladder 108 and the connecting port of the space station or space vehicle are connected, the inflatable bladder 108 may be deployed. As described above, the deployment of the inflatable bladder 108 will result in the deployment of the structural liner 112. Deployment of the inflatable bladder 108 may cause the inflatable bladder 108 to transition from a folded configuration to an unfolded configuration. The inflatable bladder 108 may be deployed by pressurizing the inflatable bladder 108. Pressurizing the inflatable bladder 108 may cause the inflatable bladder 108 to expand from a folded configuration into an unfolded configuration. In embodiments where the inflatable bladder 108 includes a connecting port 104 connected to a space station or vehicle, the inflatable bladder 108 may be deployed by pressurizing the inflatable bladder 108 to push the entire system outward, away from the space station or vehicle.

In some embodiments, pressurizing the inflatable bladder 108 causes the structural liner 112 to be deployed (for example, unfolded or unpacked) because the structural liner 112 is coupled to the inflatable bladder 108 and will adjust and/or conform to the shape and size of the bladder 108 as the bladder is inflated and once it is fully inflated. Pressurizing the inflatable bladder 108 can deploy the structural liner 112 by applying a direct force to external (for example, outer) portions of the structural liner 112. Advantageously, in some cases, applying a direct force to external portions of the structural liner 112 can obviate or reduce a need to apply a direct force to internal (for example, interior) portions of the structural liner 112 to deploy the structural liner 112. For example, in some non-limiting examples, the structural liner 112 is deployed without pressurizing the internal space 120 of the system 100 (such as, for example, by pumping a gas into the structural liner 112 to push internal portions of the structural liner 112 outward. In some embodiments, the inflatable bladder 108 can use much less gas to deploy the inflatable bladder 108 as the one or more regions 124 of the inflatable bladder 108 are much smaller than the entire volume of the structure being formed. During deployment, the internal space 120 of the structure 100 may remain a vacuum. Further, after deployment, the internal space 120 of the structure 100 may remain a vacuum. As a result, embodiments of the system 100 may not include an external source of gas configured to pressurize the internal space 120 during deployment of the structural liner 112 and may only include an external source of gas configured to pressurize the inflatable bladder 108 during deployment of the structural liner 112. In such cases, the volume of gas required to deploy the structural liner 112 can be reduced by one or more orders of magnitude. Such effective use of external sources of gas in accordance with the present disclosure can be particularly advantageous in implementations where the structural liner 112 is deployed in space. In addition, the vacuum environment within the internal space 120 of the structure 100 can be advantageous for use of the e-beam PVD systems 136 according to the present disclosure.

Moving to block 212, one or more e-beam PVD systems 136 may be provided within the internal space 120 of the structure 100, as shown and described in detail with reference to FIGS. 6A-6B. Providing the e-beam PVD systems 136 within the internal space 120 can include positioning the e-beam PVD systems 136 within the internal space 120. While one e-beam PVD system 136 is illustrated in FIGS. 6A-6B, a plurality of systems 136 may be provided within the internal space 120. For example, 1, 2, 3, 4, 5, 6, 7, 8, 9, 10 or more, 20 or more, 30 or more, 40 or more, 50 or more, 60 or more, 70 or more, 80 or more, 90 or more, or 100 or more e-beam PVD systems 136 may be used. Each e-beam PVD system may deposit the metallic material to an area having a diameter of about 0.5, 1.0, 1.5, 2.0, 2.5, 3.0, 3.5, 4.0, 4.5, 5.0 inches or more, or less, or any value or range defined by any of the preceding values, at a time. For example, the area can have a diameter of 1, 2, 4, 5, 6, 7, 8, 9, 10 inches, or more than 10 inches. The e-beam PVD systems 136 may be moved into the internal space 120 of the structure 100 through the connecting port 104. The e-beam PVD systems 136 may be supported by a frame inside the internal space 120 of the structure 100. The frame may be capable of moving and/or rotating. The e-beam PVD systems 136 supported by the frame may be moveable or rotatable relative to the frame.

In some embodiments, the one or more e-beam PVD systems 136 may be provided within the structure 100 prior to the inflatable bladder 108 being inflated or deployed. In some embodiments, the e-beam PVD systems 136 may be provided within the inflatable bladder 108 prior to delivering the inflatable bladder 108 to space. In some embodiments, the e-beam PVD systems 136 may be provided within the inflatable bladder 108 after delivery to space but prior to inflating or deploying the inflatable bladder 108. In some embodiments, the e-beam PVD systems 136 may be provided within the structure 100 after the inflatable bladder 108 is inflated. For example, in one non-limiting embodiment, the e-beam PVD systems 136 are deployed inside a volume defined by the structural liner 112 after the inflatable bladder 108 is inflated.

Moving to block 216, a metallic structural shell 114, as shown in FIGS. 6A-6B, may be deposited on the structural liner 112 within the internal space 120 of the structure 100. The thickness of the metallic structural shell 114 is not necessarily drawn to scale and is to aid in describing embodiments of the present disclosure. The relative dimensions and proportions as shown are not intended to limit the present disclosure. The structural liner 112 and the metallic structural shell 114 may become one structural element of the structure 100. The metallic structural shell 114 may be deposited on the structural liner 112 using the one or more e-beam PVD systems 136. FIG. 6A illustrates an incomplete or partial layer of metal deposited during the formation of the metallic structural shell 114. FIG. 6B illustrates a uniform or substantially uniform metallic structural shell 114 that has been formed. The metallic structural shell 114 of FIG. 6B has a substantially uniform thickness and the entire surface, or substantially all of the entire surface, of the structural liner 112 has been covered by the metallic structural shell 114.

During formation of the metallic structural shell 114, the e-beam PVD systems 136 may sequentially deposit a plurality of metallic layers on the structural liner 112. In embodiments including more than one e-beam PVD system, the e-beam PVD systems 136 may be operating simultaneously depositing the metallic layers. For example, the e-beam PVD systems 136 may be operating simultaneously and work together to sequentially deposit the plurality of metallic layers on the structural liner 112. The e-beam PVD systems 136 may form an array of systems constantly moving within the internal space 120 to uniformly deposit the metallic layers. The e-beam PVD systems 136 may move in any linear direction and/or rotate as needed to uniformly deposit the metallic layers.

The layers of material deposited to form the metallic structural shell 114 may seal the volume defined by the internal surface 113 of the structural liner 112. In some embodiments, the layers of material may not be intended to withstand forces exerted on the structure 100 in a space environment, but are sufficiently strong to provide stiffness to the structural liner 112, which may carry the majority of the load and can be more mass efficient. Together, the structural liner 112 and the metallic structural shell 114 can have sufficient rigidity and stiffness to withstand forces exerted on the structure 100 in a space environment (both external to the system 100 and internal to the system 100). In example embodiments in which deposition of the metallic layers takes place in space, the vacuum environment outside the structure 100 and the vacuum environment within the internal space 120 provides for an advantageous environment for the use of e-beam PVD as a vacuum environment is ideal for e-beam PVD. The metallic structural shell 114 may provide a rigid structural interior to the structure 100. The metallic structural shell 114 may pneumatically seal the structure 100. The sealing and rigidizing of the structural liner 112 with the metallic structural shell 114 can transform the structure 100 into a permanent habitat capable of use in space. The rigidity of the metallic structural shell 114 may be advantageous as it allows for system integration. For example, the rigidity of the metallic structural shell 114 can allow windows and docking ports to be incorporated in the structure 100. The rigidity of the metallic structural shell 114 may allow for items or structures for internal use to be physically attached to the metallic structural shell 114. Non-limiting examples of items or structures for internal use include shelving, storage space, artwork, and appliances.

The metallic structural shell 114 may have a thickness of about 1.0, 1.1, 1.2, 1.3, 1.4, 1.5, 1.6, 1.7, 1.8, 1.9, 2.0, 2.0, 2.1, 2.2, 2.3, 2.4, 2.5, 2.6, 2.7, 2.8, 2.9, 3.0, 3.1, 3.2, 3.3, 3.4, 3.5, 3.6, 3.7, 3.8, 3.9, or 4.0 mm or more, or any value or range defined by any of the preceding values. In some embodiments, the thickness of the metallic structural shell may be about 2 mm to about 3 mm, though in some embodiments the thickness may be outside this range. Each layer of material of the metallic structural shell 114 may have a constant thickness or a small variation in thickness. The metallic structural shell 114 may increase in thickness as it is formed. For example, the metallic structural shell 114 may be 1.0 mm thick after 6 days of material deposition, 2.0 mm thick after 12 days of material deposition, and 2.99 mm thick after 29 days of material deposition. Advantageously, in some embodiments, the intermediate and final thickness of the metallic structural shell 114 can be predetermined and/or controlled precisely as the rate of deposition of materials using e-beam PVD systems can be relatively slow. The use of the structural liner 112 and the metallic structural shell 114 together can allow for the metallic structural shell 114 to be a relatively thin layer (for example, as compared to the overall outer dimensions of the structure 100), which can allow for a faster, more efficient deposition of the metallic structural shell 114. In some embodiments, the structural liner 112 may not be used and the metallic structural shell 114 may be deposited directly on the internal wall 116 of the inflatable bladder 108 (or other suitable structure). If the structural liner 112 is not used, the metallic structural shell 114 may have a thickness of about 1, 2, 3, 4, 5, 6, 7, 8, 9, 10 mm or more, or any value or range defined by the preceding values. In some embodiments, the metallic structural shell 114 have a thickness between about 1 inch to about 6 inches, though in some embodiments, the metallic structural shell 114 may have a thickness outside this range.

During deposition of the metallic structural shell 114, the one or more e-beam PVD systems 136 may be constantly moving within the internal space 120 of the structure 100. The constant movement of the one or more e-beam PVD systems 136 may provide for a more uniform deposition of the metallic structural shell 114. The use of more than one e-beam PVD system 136 in some embodiments of the present disclosure may reduce the overall time needed to deposit the metallic structural shell 114, as the deposition of the metallic structural shell 114 may be a slow process in some cases. For example, using an about 100 meter diameter structure as a non-limiting example, it may take one or more e-beam PVD systems 136 about 6 months to form a complete metallic structural shell 114. Using an about 10 meter diameter structure as a non-limiting example, it may take one or more e-beam PVD systems 136 about 18 days to form a complete metallic structural shell 114. While 10 meter and 100 meter diameter structures are used as examples, the structure 100 may have a diameter of about 5, 6, 7, 8, 9, 10, 25, 50, 75, 100 meters or more, or less or any value or range defined by any of the preceding values. The size of the structure 100 and/or the number of e-beam PVD systems 136 used may impact the length of the deposition time. For example, an increase in the number of e-beam PVD systems 136 may decrease the overall deposition time and/or a decrease in the size of the structure 100 may decrease the overall deposition time. The relatively slow deposition process for forming the metallic structural shell 114 may be advantageous in some instances, as the slow process may ensure a more uniform equal coverage of the metallic structural shell 114.

In some examples, the method 200 ends at block 216 after the metallic structural shell 114 is deposited on the structural liner. In other examples described below, the method 200 can include additional blocks during which further processing is performed. In addition, it will be understood that the method 200 need not be performed in the order described and/or some steps may be omitted.

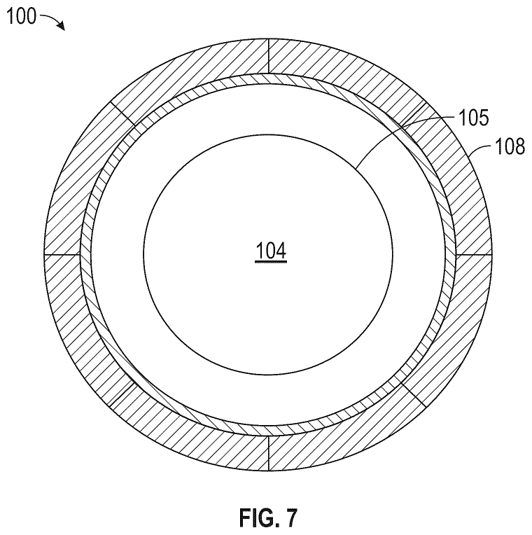

Further processing may be implemented on structures 100 that include a connection to a space craft of a space station according to the present disclosure. For example, in non-limiting examples of structures 100 that are connected to a space craft or a space vehicle via a connecting port, further processing may be implemented to allow access between the space craft or vehicle and the structure 100. In some embodiments, the connecting port may not be covered by material during the deposition process. For example, the metallic structural shell 114 may be formed around but not over the connecting port. In other embodiments, after depositing the metallic structural shell 114, a portion of the metallic structural shell 114 covering the connection between the connecting port 104 and the inflatable bladder 108 may have sealed the connecting port 104 and the inflatable bladder together such that the internal space 120 may not be accessible without further processing. For example, as shown in FIG. 7, an outer perimeter 105 of the connecting port 104 may be sealed shut such that a door of the connecting port 104 may not open to allow access within the internal space 120. FIG. 7 illustrates a cross-sectional view of the structure 100 taken along the line 7-7 labeled in FIG. 1. The metallic structural shell 114 may prevent the opening of the door. Upon completion of the formation of the metallic structural shell 114, the portion of the metallic structural shell 114 deposited around the outer perimeter 105 of the connecting port 104 may be removed to allow access to the internal space 120 of the structure 100.

Further processing may be implemented on structures 100 that include one or more windows or viewing ports or other openings to the external atmosphere. In some embodiments, the one or more windows or viewing ports may not be covered by material during the deposition process. For example, the metallic structural shell 114 may be formed around but not over the one or more windows or viewing ports. In other embodiments, after depositing the metallic structural shell 114, the one or more windows or viewing ports may not be accessible or visible without further processing. For example, the metallic structural shell 114 may block a user from viewing an environment external to the structure 100 (for example, outer space) through the windows or viewing ports. Upon completion of the formation of the metallic structural shell 114, the portion of the metallic structural shell 114 deposited over the windows or viewing ports may be removed to allow a user to view an external environment through the window or viewing port of the structure 100. Advantageously, in some embodiments of the present disclosure, once formation of the metallic structural shell 114 is complete, one or more windows, doors, coverings, or other structures can be installed on or over openings to the external atmosphere to close and/or seal the metallic structural shell 114, at which time the volume of the metallic structure shell 114 can be pressurized.

While the above detailed description has shown, described, and pointed out novel features of the present disclosure as applied to various embodiments, it will be understood that various omissions, substitutions, and changes in the form and details of the device or process illustrated may be made by those skilled in the art without departing from the spirit of the present disclosure. As will be recognized, the present disclosure may be embodied within a form that does not provide all of the features and benefits set forth herein, as some features may be used or practiced separately from others. All changes which come within the meaning and range of equivalency of the claims are to be embraced within their scope.

The detailed description is directed to certain specific embodiments of the present disclosure. Reference in this specification to “one embodiment,” “an embodiment,” or “in some embodiments” means that a particular feature, structure, or characteristic described in connection with the embodiment is included in at least one embodiment of the present disclosure. The appearances of the phrases “one embodiment,” “an embodiment,” or “in some embodiments” in various places in the specification are not necessarily all referring to the same embodiment, nor are separate or alternative embodiments necessarily mutually exclusive of other embodiments. Moreover, various features are described which may be exhibited by some embodiments and not by others.

Various embodiments have been described with reference to the accompanying figures, wherein like numerals refer to like elements throughout. The terminology used in the description presented herein is not intended to be interpreted in any limited or restrictive manner, simply because it is being utilized in conjunction with a detailed description of certain specific embodiments of the development. Furthermore, embodiments of the present disclosure may include several novel features, no single one of which is solely responsible for its desirable attributes or which is essential to practicing the present disclosure.

The term “comprising” as used herein is synonymous with “including,” “containing,” or “characterized by,” and is inclusive or open-ended and does not exclude additional, unrecited elements or method steps. With respect to the use of substantially any plural and/or singular terms herein, those having skill in the art may translate from the plural to the singular and/or from the singular to the plural as is appropriate to the context and/or application. The various singular/plural permutations may be expressly set forth herein for sake of clarity.

It will be understood by those within the art that, in general, terms used herein are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations.

In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

All numbers expressing quantities, dimensions, and so forth used in the specification and claims are to be understood as being modified in all instances by the term “about.” Accordingly, unless indicated to the contrary, the numerical parameters set forth in the specification are approximations that may vary depending upon the desired properties sought to be obtained by embodiments of the present disclosure. At the very least, and not as an attempt to limit the application of the doctrine of equivalents to the scope of the claims, each numerical parameter should be construed in light of the number of significant digits and ordinary rounding approaches. For example, terms such as about, approximately, substantially, and the like may represent a percentage relative deviation, in various embodiments, of ±1%, ±5%, ±10%, or ±20%.

The above description discloses several devices, methods, and materials of the present disclosure. The present disclosure is susceptible to modifications in the devices, methods, and materials, as well as alterations in the fabrication methods and equipment. Such modifications will become apparent to those skilled in the art from a consideration of this disclosure. Consequently, it is not intended that the present disclosure be limited to the specific embodiments disclosed herein, but that it covers all modifications and alternatives coming within the true scope and spirit of the present disclosure.

What is claimed is:

1. A kit for manufacturing a structure in space, the kit comprising:
an inflatable bladder having an internal wall configured to define an internal space of the structure when the bladder is inflated;
a structural liner coupled to the internal wall of the inflatable bladder; and
one or more e-beam physical vapor deposition systems configured to be positioned within the internal space of the structure when the bladder is inflated, the one or more e-beam physical vapor deposition systems configured to form a metallic structural shell on the structural liner.

2. The kit of claim 1, wherein the structural liner comprises a braided carbon fiber liner.

3. The kit of claim 1, wherein the structural liner comprises a ceramic material.

4. The kit of claim 1, wherein the metallic structural shell is formed from a high stiffness and high strength alloy.

5. The kit of claim 4, wherein the alloy is titanium or aluminum.

6. The kit of claim 1, further comprising a frame configured to support the one or more e-beam physical vapor deposition systems.

7. The kit of claim 6, wherein the frame is configured to move within the internal space while creating the metallic structural shell.

8. The kit of claim 6, wherein the frame is configured to move the one or more e-beam physical vapor deposition systems.

9. The kit of claim 1, wherein the one or more e-beam physical vapor deposition systems are configured to sequentially deposit a plurality of metallic layers on the structural liner to form the metallic structural shell.

10. The kit of claim 1, wherein the one or more e-beam physical vapor deposition systems are configured to be positioned within the inflatable bladder before it is inflated.

11. The kit of claim 1, wherein an internal surface of the structural liner is configured to define a volume when the bladder is inflated, and wherein the one or more e-beam physical vapor deposition systems are configured to seal the volume defined by the internal surface of the structural liner.

12. The kit of claim 1, further comprising a gas source configured to inflate the bladder.

13. The kit of claim 12, wherein the inflatable bladder is configured to transform from a folded configuration to an unfolded configuration when gas from the gas source inflates the bladder.

14. The kit of claim 1, wherein the one or more e-beam physical vapor deposition systems are configured to form a metallic structural shell on the structural liner that is about 2 mm to about 3 mm thick.

15. A method of manufacturing a structure comprising:
attaching a structural liner to an internal wall of an inflatable bladder;
deploying the inflatable bladder and structural liner by pressurizing the inflatable bladder;
positioning one or more e-beam physical vapor deposition systems within an internal space of the structure; and
forming a metallic structural shell on the structural liner using the one or more e-beam physical vapor deposition systems.

16. The method of claim 15, wherein the one or more e-beam physical vapor deposition systems are positioned within the inflatable bladder before the inflatable bladder is deployed.

17. The method of claim 15, wherein forming the metallic structural shell comprises sequentially depositing a plurality of metallic layers on the structural liner.

18. The method of claim 15, wherein forming the metallic structural shell comprises depositing a plurality of metallic layers to a thickness of about 2 mm to about 3 mm.

19. The method of claim 15, wherein the structural liner is a braided carbon fiber liner.

20. The method of claim 15, wherein the structural liner is a ceramic material.

21. The method of claim 15, wherein the metallic structural shell is formed from a high stiffness and high strength alloy.

22. The method of claim 21, wherein the alloy is titanium or aluminum.

23. The method of claim 15, further comprising moving the one or more e-beam physical vapor deposition systems while forming the metallic structural shell.

24. The method of claim 15, wherein a vacuum environment exists within a volume defined by the structural liner after deploying the inflatable bladder and the structural liner.

25. The method of claim 15, wherein deploying the inflatable bladder and structural liner occurs in space.

26. The method of claim 15, wherein forming the metallic structural shell seals a volume defined by the structural liner.

27. The method of claim 15, wherein deploying the inflatable bladder transforms the structural liner from a folded configuration to an unfolded configuration.

28. A structure comprising:
an inflatable bladder having an internal wall configured to define an internal space when inflated;
a structural liner coupled to the internal wall of the inflatable bladder; and
a metallic structural shell deposited on the structural liner by one or more e-beam physical vapor deposition systems.

29. The structure of claim 28, wherein the metallic structural shell is from about 2 mm to about 3 mm thick.

30. The structure of claim 28, wherein the structural liner is a braided carbon fiber liner.

31. The structure of claim 28, wherein the metallic structural shell is formed from a high stiffness and high strength alloy.
